(19) United States
(12) Patent Application Publication
(10) Pub. No.: US 2007/0211551 A1
(43) Pub. Date: Sep. 13, 2007

(54) Method for dynamic performance optimization conforming to a dynamic maximum current level

(76) Inventors: Yoav Yogev, Maskeret-Batia (IL); Kobi Danon, Rishon Lezion (IL)

Correspondence Address: EMPK & SHILOH, LLP, 116 JOHN ST,, SUITE 1201, NEW YORK, NY, 10038, US

(21) Appl. No.: 11/603,905

(22) Filed: Nov. 24, 2006

Related U.S. Application Data
(60) Provisional application No. 60/739,450, filed on Nov. 25, 2005.

(51) Int. Cl. G11C 5/14

(52) U.S. Cl. 365/226

(57) ABSTRACT

Various non-limiting exemplary embodiments are disclosed including a method for power management in a system comprising determining a maximum system current level, and allocating current to one or more operations each having a minimum operation current level and a maximum operation current level such that the total allocated current for the one or more operations does not exceed the maximum system current level.

### BACKGROUND

Exemplary embodiments disclosed herein pertain to digital memory used in digital electronic devices. More particularly, exemplary embodiments disclosed herein pertain to flash memory devices.

Computers use RAM to hold the program code and data during computation. A defining characteristic of RAM is that all memory locations can be accessed at almost the same speed. Most other technologies have inherent delays for reading a particular bit or byte. Adding more RAM is an easy way to increase system performance.

Early main memory systems built from vacuum tubes behaved much like modern RAM, except the devices failed frequently. Core memory, which used wires attached to small ferrite electromagnetic cores, also had roughly equal access time (the term “core” is still used by some programmers to describe the RAM main memory of a computer). The basic concepts of tube and core memory are used in modern RAM implemented with integrated circuits

Alternative primary storage mechanisms usually involved a non-uniform delay for memory access. Delay line memory used a sequence of sound wave pulses in mercury-filled tubes to hold a series of bits. Drum memory acted much like the modern hard disk, storing data magnetically in continuous circular bands.

Many types of RAM are volatile, which means that unlike some other forms of computer storage, such as disk storage and tape storage, they lose all data when the computer is powered down. Modern RAM generally stores a bit of data as either a charge in a capacitor, as in “dynamic RAM,” or the state of a flip-flop, as in “static RAM.”

Non-Volatile Random Access Memory (NVRAM) is a type of computer memory chip which does not lose its information when power is turned off. NVRAM is mostly used in computer systems, routers and other electronic devices to store settings which must survive a power cycle (like number of disks and memory configuration). One example is the magnetic core memory that was used in the 1950s and 1960s.

The many types of NVRAM under development are based on various technologies, such as carbon nanotube technology, magnetic RAM (MRAM) based on the magnetic tunnel effect, Ovonic Unified Memory based on phase-change technology, and FeRAM based on the ferroelectric effect. Today, most NVRAM is Flash memory, which is used primarily in cell phones and portable MP3 players.

Flash memory is non-volatile, which means that it does not need power to maintain the information stored in the chip. In addition, flash memory offers fast read access times (though not as fast as volatile DRAM memory used for main memory in PCs) and better shock resistance than hard disks. These characteristics explain the popularity of flash memory for applications such as storage on battery-powered devices.

Flash memory stores information in an array of floating gate transistors, called “cells”, each of which traditionally stores one bit of information. Newer flash memory devices, sometimes referred to as multi-level cell devices, can store more than 1 bit per cell, by varying the number of electrons placed on the floating gate of a cell.

NOR-based flash has long erase and write times, but has a full address/data (memory) interface that allows random access to any location. This makes it suitable for storage of program code that needs to be infrequently updated, such as a computer's BIOS (basic input output software) or the firmware of set-top boxes. Its endurance is 10,000 to 1,000,000 erase cycles. NOR-based flash was the basis of early flash-based removable media; Compact Flash was originally based on it, though later cards moved to the cheaper NAND flash.

In NOR flash, each cell looks similar to a standard MOSFET, except that it has two gates instead of just one. One gate is the control gate (CG) like in other MOS transistors, but the second is a floating gate (FG) that is insulated all around by an oxide layer. The FG is between the CG and the substrate. Because the FG is isolated by its insulating oxide layer, any electrons placed on it get trapped there and thus store the information.

When electrons are on the FG, they modify (partially cancel out) the electric field coming from the CG, which modifies the threshold voltage (Vₜ) of the cell. Thus, when the cell is “read” by placing a specific voltage on the CG, electrical current will either flow or not flow, depending on the Vₜ of the cell, which is controlled by the number of electrons on the FG.

This presence or absence of current is sensed and translated into 1's and 0's, reproducing the stored data. In a multi-level cell device, which stores more than 1 bit of information per cell, the amount of current flow will be sensed, rather than simply detecting presence or absence of current, in order to determine the number of electrons stored on the FG.

A NOR flash cell is programmed (set to a specified data value) by starting up electrons flowing from the source to the drain, then a large voltage placed on the CG provides a strong enough electric field to suck them up onto the FG, a process called hot-electron injection.

To erase (reset to all 1's, in preparation for reprogramming) a NOR flash cell, a large voltage differential is placed between the CG and source, which pulls the electrons off through quantum tunneling. In single-voltage devices (virtually all chips available today), this high voltage is generated by an on-chip charge pump.

Most modern NOR flash memory components are divided into erase segments, usually called either blocks or sectors. All of the memory cells in a block must be erased at the same time. NOR programming, however, can generally be performed one byte or word at a time.

Low-level access to a physical flash memory by device driver software is different from accessing common memories. Whereas a common RAM will simply respond to read and write operations by returning the contents or altering them immediately, flash memories need special considerations, especially when used as program memory akin to a read-only memory (ROM).

While reading data can be performed on individual addresses on NOR memories unlocking (making available for erase or write), erasing and writing operations are performed block-wise on all flash memories. A typical block size will be 64, 128, or 256 KiB or higher.

The read-only mode of NOR memories is similar to reading from a common memory, provided address and data bus is mapped correctly, such that NOR flash memory is much like any address-mapped memory. NOR flash memories can be used as execute-in-place memory, meaning it behaves as a ROM memory mapped to a certain address.

When unlocking, erasing or writing NOR memories, special commands are written to the first page of the mapped memory. These commands are defined as the common flash interface (defined by Intel Corporation of Santa Clara, California) and the flash circuit will provide a list of all available commands to the physical driver.

NAND Flash uses tunnel injection for writing and tunnel release for erasing. NAND flash memory forms the core of the removable USB interface storage devices known as “keydrives.”

NAND flash memories cannot provide execute-in-place due to their different construction principles. These memories are accessed much like block devices such as hard disks or memory cards. When executing software from NAND memories, virtual memory strategies are used: memory contents must first be paged into memory-mapped RAM and executed there, making the presence of a memory management unit (MMU) on the system absolutely necessary.

Because of the particular characteristics of flash memory, it is best used with specifically designed file systems which spread writes over the media and deal with the long erase times of NOR flash blocks. The basic concept behind flash file systems is: when the flash store is to be updated, the file system will write a new copy of the changed data over to a fresh block, remap the file pointers, then erase the old block later when it has time.

One limitation of flash memory is that although it can be read or programmed a byte or a word at a time in a random access fashion, it must be erased a “block” or “sector” at a time. Starting with a freshly erased block, any byte within that block can be programmed. However, once a byte has been programmed, it cannot be changed again until the entire block is erased. In other words, flash memory (specifically NOR flash) offers random-access read and programming operations, but cannot offer random-access rewrite or erase operations.

When compared to a hard disk drive, a further limitation is the fact that flash memory has a finite number of erase-write cycles (most commercially available EEPROM products are guaranteed to withstand 10⁶ programming cycles), so that care has to be taken when moving hard-drive based applications, such as operating systems, to flash-memory based devices such as CompactFlash. This effect is partially offset by some chip firmware or file system drivers by counting the writes and dynamically remapping the blocks in order to spread the write operations between the sectors, or by write verification and remapping to spare sectors in case of write failure.

Flash memory devices of the prior art utilize current according to the operations being performed. Each operation consumes fixed current at a fixed performance level. Current usage rises and falls based on the type of operation being performed. These operations are performed serially; one operation must wait until another completes.

Flash memory devices are used in a variety of environments which imply dynamically changing power sources. Although the supply of current may increase or decrease, the current consumption of flash devices of the prior art is unresponsive to these changes.

Since the current consumption of the prior art flash devices is unresponsive, it is sometimes too low and does not utilize available current to perform at a high rate of speed.

Another limitation of the prior art flash devices is that they may inadvertently exceed a maximum current limit, causing a system failure, such as a “system hang” of a laptop computer.

These and other limitations of the prior art will apparent to those of skill in the art upon a reading following descriptions and a study of the several of the drawing.

### SUMMARY

Certain non-limiting exemplary embodiments provide an improved system consisting of a controller and flash devices capable of dynamically changing its power consumption by changing an internal constant which controls the rate at which data is processed. The internal constant, a “K-value” is the parameter in the flash that controls the trade-off between speed and current consumption. By dynamically altering K-value, it is possible to reduce current consumption when the current consumption levels approach the budgeted current limit of, for example, 70 to 80 milliamps. As is well known to those skilled in the art, current consumption is usually highest during program and erase operations. More generally, a high speed or high power mode may be used in the flash or other non-volatile memory (NVM) device. In this mode, the NVM uses more energy in order to improve its performance.

During periods of high activity in the flash, and especially during program and erase operations, current levels may approach the current limit. Failure to maintain current consumption within the current limit may result in various system failure modes, including but not limited to a system “hang”, such as with a laptop computer.

In accordance with certain embodiments, different operations can be performed in parallel to achieve higher performance. For example, a read operation can be performed in parallel with an erase operation. Concurrent operations such as these may induce an over-current condition if too many of them are performed at the same time. By modeling or dynamically measuring current usage, this kind of problem can be anticipated, and a new K-value can be selected according to present operating conditions which avoids the over-current problem. In one embodiment, a toggle mode is used to prevent operations from occurring concurrently when such concurrency would cause an over-current condition. In another embodiment, the same concurrency would be permitted but with a lower K-value.

The dynamic K-value can also be used to gain higher performance when current consumption is low. For example, the flash controller consumes power when orchestrating communications between the various components. Once an operation has begun, however, the power consumption in the controller is reduced because it pertains to initiating the operation but does not continue during the operation. Alternatively, controller power consumption could be reduced because of other activities unrelated to the operation regarding management of wear leveling, etc. In any case, when the controller detects that current consumption will be reduced, it can signal to the flash that it may operate at a higher K-value even after an operation has already commenced. Thus, a portion of the operation is performed at a lower K-value and another portion of the operation is performed at a higher K-value. It is contemplated that many such K-value changes can be performed during an operation. In general, the K-value can be changed at any point before, during or after an operation to achieve the proper current consumption and maximum performance within that current consumption budget.

As will be appreciated by those skilled in the art, current consumption within any device such as, for example, a camera varies over time. In one embodiment, the flash device would be allocated a fixed current budget of, for example, 70 to 80 milliamps. In another embodiment, this budget could be dynamic. The host may communicate the budget to the flash device in a special communication mode at the driver level This budget can be the result of direct measurement or modeling by the host of the overall current budget of the device as a whole. This embodiment is just one of many possible alternatives to overall current consumption budgeting.

The dynamic K-value can provide an improved data transfer rate for the NROM based flash card using dynamic power management and, as a result, may provide up to a 50% faster data rate. As will be appreciated by those skilled in the art, these techniques may be used in any non-volatile memory system or, in fact, in any non-volatile memory application, such as a cell, an array, an embedded array, a card, etc. In accordance with the dynamic K-value method, it is necessary to develop a table which enumerates each component according to its power consumption values in its various operational modes. These components include, for example, the card interface, the controller, the FIFO, and the flash. Since these various components have multiple operational modes, the power consumption levels for each mode must be enumerated in order to model the power consumption of the flash.

In certain embodiments, only some of the various components would be mapped into a table defining power consumption in the various modes of operation. Certain embodiments activate only the minimum components needed to conduct a specific operation and depend upon the flash device having a model of power consumption and a knowledge, of the permitted current limit and subsequently adjust K-value and the on/off power status of the various components to consume the permitted level. The controller is able to manage power budgeting in all of the various operational modes; in certain embodiments, operations are done in power-absolute sequential manner.

In certain situations, the flash device is supplied with an abundance of power and is relatively unconstrained regarding power consumption. In this mode, maximum parallelism is used to achieve the greatest performance increase; the controller is active all the time. By activating some or all of the components in parallel, various operations such as read operations, write operations, and erase operations are performed concurrently. In some cases, multiple operations of the same type may be performed in parallel. As a non-limiting example, multiple erase operations may be performed at the same time in certain embodiments.

This maximum parallelism is an emergent property of the embodiments described herein; as the current budget increases more and more concurrency is achieved. This graceful scaling of power consumption to utilize available power may be achieved by a variety of embodiments. In one embodiment, a set of rules is implemented in the hardware and software of the flash device. An example of such a rule is: when a certain phase of an operation is reached (prior to the end or at the end of the operation), signal availability so that another operation may commence. Another example of such a rule is to initiate an operation at a certain power level, and then, upon completion of various management and controller operations, the controller enters a sleep mode. Optionally, the performance of any operations in progress in other portions of the flash device may be boosted to proceed at a higher performance levels in order to make use of the power that is made available by the controller's auto sleep.

An alternative to the rule based scheme is to implement a scheduler which applies a performance metric to optimize the operation of the device within the current limit. An example of such a metric is overall throughput of the flash device.

Once the current level reaches a certain point, there is such an abundance of current that it is possible to perform with maximum parallelism. It should be noted that this maximum parallelism mode may be initiated during the normal operation of the flash device. It is also possible to exit the maximum parallelism mode or other modes dynamically. A non-limiting example of a situation in which maximum parallelism is possible would be a flash device connected to a laptop computer which is plugged into the wall. Since this kind of condition can be entered and exited at the discretion of the user, the flash device is dynamic with respect to this condition according to certain non-limiting embodiments.

As will be appreciated by those skilled in the art, flash memory must be erased before data can be written or programmed into it. It is the responsibility of the controller to maintain a logical to physical mapping between the logical address space used by the host and the physical address space used within the flash. When writing or programming a specific portion of the logical address space the data may be written to an entirely new physical location which is distinct and separate from the previous physical location associated with that logical address. At some point, the physical location which contained the previous data for that logical address must be erased so that the storage can be reused. These erase operations may, however, be deferred. Similarly, wear-leveling operations induce various data moves and erasures during flash operation. These data moves and erasures can be performed in the background during idle time or concurrently with various operations induced by host activity such as read and write operations.

Certain embodiments advantageously increase the operations performed in the background when power is abundant or the device is idle. The controller may, in certain embodiments, employ a prioritization technique which will alter the order in which these background operations are performed. One advantage of this kind of reordering of operations is that it can have an enhancing effect on write performance which is a well-known bottleneck in flash memory performance. As an example, the controller may use locality of reference to predict which portions of the logical address space are likely to be written in the near future. By boosting the priority of maintenance operations in areas of the flash that are likely to be written in the near future, a performance enhancement is achieved.

These and other embodiments and advantages and other features disclosed herein will become apparent to those of skill in the art upon a reading of the following descriptions and a study of the several figures of the drawing.

### BRIEF DESCRIPTION OF THE DRAWINGS

Several exemplary embodiments will now be described with reference to the drawings, wherein like components are provided with like reference numerals. The exemplary embodiments are intended to illustrate, but not to limit, the invention. The drawings include the following figures:

FIG. 1 is a block diagram depicting an exemplary flash memory device coupled to a host device, and various exemplary components of the flash memory device including a controller, an interface, a volatile memory and a non-volatile memory;

FIG. 2 is a flow diagram depicting an exemplary operation of the controller of FIG. 1;

FIG. 3 is a data flow diagram depicting an exemplary operation “run controller sub-processes” in greater detail;

FIG. 4 is a diagram depicting an exemplary aspect of an exemplary embodiment of an executive operation depicted in FIG. 3 in greater detail;

FIG. 5 is a diagram depicting a completion of an operation of FIG. 4;

FIG. 6 is a diagram depicting an exemplary reallocation of current subsequent to the completion of an operation of FIG. 4;

FIG. 7 is a flow diagram depicting an exemplary scheduler operation of FIG. 3 which produces a schedule;

FIG. 8 is a table representing an exemplary conflict table data structure;

FIG. 9 is a table representing an exemplary current consumption table of FIG. 3; and

FIG. 10 is a flow diagram depicting an exemplary evaluate case with respect to best case operation, for process 26 shown and described with relation to FIG. 7.

### DETAILED DESCRIPTION OF EXEMPLARY EMBODIMENTS

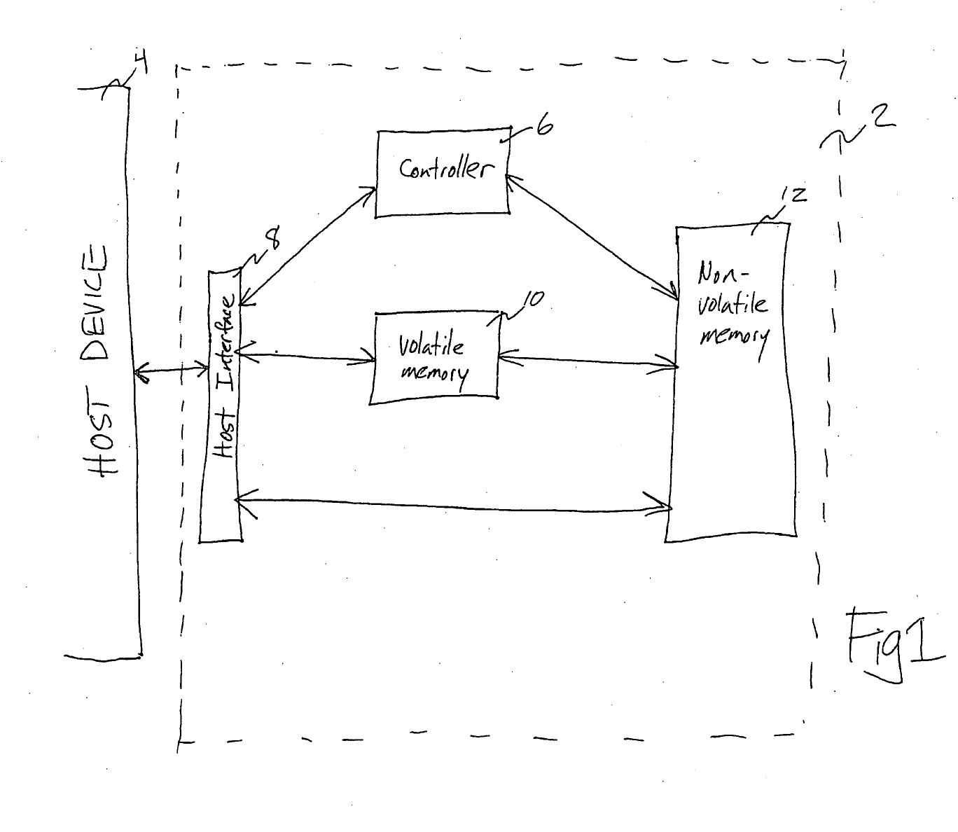

FIG. 1 is a block diagram depicting an exemplary non-volatile memory system 2 which is coupled to a host device 4. There are many examples of a host device 4, such as a laptop computer, a digital camera, a dictation machine, etc. Non-volatile memory system 2 is comprised of a controller 6, a host interface 8, volatile memory 10, and non-volatile memory 12. In certain embodiments, controller 6 is coupled to each of host interface 8, volatile memory 10 and non-volatile memory 12 and performs a function of controlling and orchestrating the activities of these components. When non-volatile memory system 2 is installed in a host device 4, host interface 8 is coupled to host device 4. In certain embodiments, non-volatile memory system 2 draws power from host device 4 via host interface 8. Power is distributed throughout the various components of non-volatile memory system 2 and these connections are not shown in FIG. 1. Host interface 8 is coupled to controller 6 and receives commands from controller 6 as well as reporting various events to controller 6 by said coupling. In certain embodiments, information reported to controller 6 by host interface 8 comprises at least one interrupt. Host interface 8 is coupled to volatile memory 10 which it uses to buffer information. Data received from host device 4 passes through host interface 8 and is stored in volatile memory 10. The reason that this information needs to be buffered in volatile memory 10 is that the rate at which data can be written to non-volatile memory 12 is slower than the rate at which information can be received from host device 4. As will be appreciated by those skilled in the art, this arrangement allows for optimized 10 with host device 4. Volatile memory 10 is coupled to non-volatile memory 12 in certain embodiments. Information received from host-device 4 via host interface 8 and which is subsequently stored in volatile memory 10 can be moved by means of a program operation to non-volatile memory 12. This kind of operation is somewhat time consuming and also consumes substantial amounts of power. Controller 6 is coupled to volatile memory 10 and non-volatile memory 12 and commands these components to perform various functions including moving data from volatile memory 10 to non-volatile memory 12, moving data from non-volatile memory 12 to volatile memory 10, erasing portions of non-volatile memory 12, and reading information from non-volatile memory 12 and transmitting it to host device 4 via host interface 8. In some embodiments, host interface 8 is coupled directly to non-volatile memory 12; in other embodiments data movement between host interface 8 and non-volatile memory 12 must go through volatile memory 10. In certain embodiments, Write operations must pass through volatile memory 10 and read operations may bypass volatile memory 10.

Certain embodiments use direct memory access to improve performance. As will be appreciated by those of skill in the art, direct memory access allows non-volatile memory system 2 to drive an 10 operation with respect to host device 4.

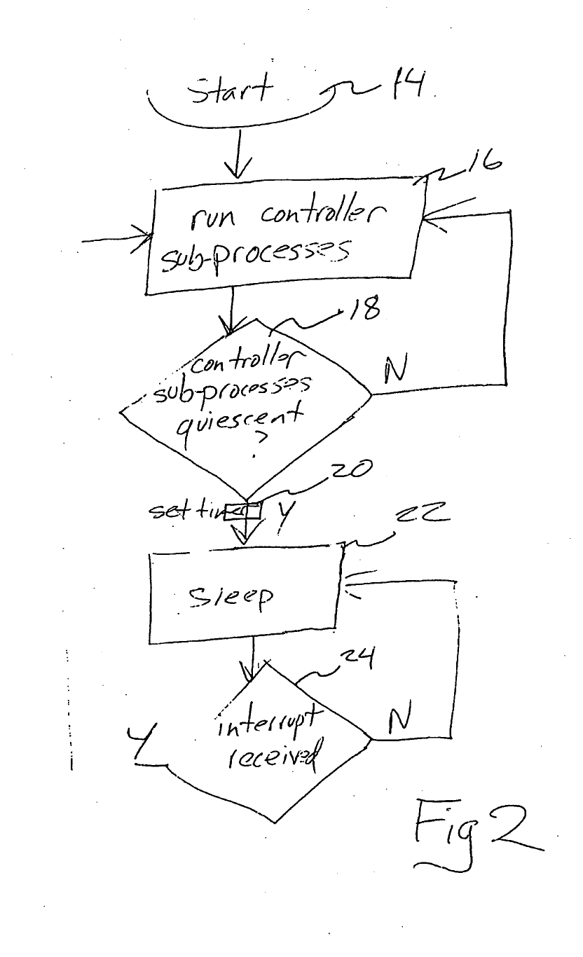

FIG. 2 is a flow diagram depicting an internal process of controller 6. The process begins in an operation 14 and continues in an operation 16 wherein various sub-processes of controller 6 are performed in part or in whole. Subsequent to operation 16, an operation 18 determines whether the sub-processes of controller 6 are presently quiescent. If the sub-processes are not quiescent, control passes back to operation 16 which continues processing. If, in operation 18, it is determined that the controller 6 sub-processes are quiescent then control passes to an operation 20 which sets a timer which later results in an interrupt. In some embodiments, operation 20 is not present. Then, in an operation 22, a sleep mode is entered in which controller 6 is deprived of power. In some embodiments, controller 6 simply enters a low power state and in other embodiments, it is entirely deprived of power, with a smaller circuit or controller remaining online in order to re-power the controller when a signal is received or a time limit has been reached, for example. In an operation 24, it is determined whether or not an interrupt has been received. If an interrupt has not been received in operation 24, control passes back to operation 22 which continues the sleep operation. If, however, it is determined in operation 24 that an interrupt has been received, control passes to operation 16 which powers up the controller 6 and runs the various processes of the controller 6. The interrupt received may indicate the completion of a task by non-volatile memory 12, volatile memory 10, or host interface 8. The interrupt may also be due to a timer. Communication from host device 4 with host interface 8 may also result in an interrupt. As will be appreciated by those of skill in the art, various other events may induce an interrupt as well. The process depicted in FIG. 2 continues indefinitely until non-volatile memory system 2 is deprived of power by host device 4 or is removed from host device 4.

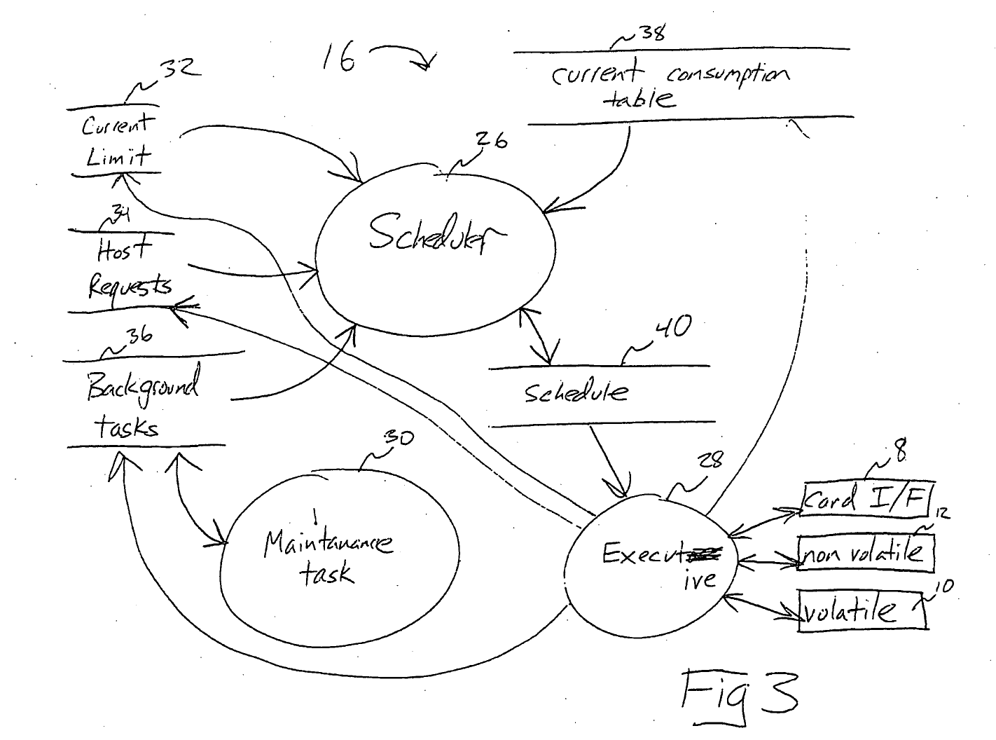

FIG. 3 is a flow diagram depicting one example of the various sub-processes of operation 16 of FIG. 2 as well as various data structures and hardware devices pertaining to said sub-processes. It is important to note that this is only one example and there are many alternatives. The point of this example is to illustrate one possible structure that could be used to optimize performance within a fixed or dynamically changing current limit.

Scheduling and performance optimization of multiple concurrent tasks may be approached in a variety of ways.

Exemplary embodiments include scheduler 26, executive 28 and maintenance task 30. The various data structures used by these processes include current limit 32, host requests 34, background tasks 36, current consumption table 38 and schedule 40. In addition to interacting with these data structures, the sub-processes of FIG. 3 also interact with various hardware devices including host interface 8, non-volatile memory 12 and volatile memory 10. The various sub-processes of FIG. 3 may also interact with host device 4 of FIG. 1 via host interface 8. Executive 28 is responsible for sending commands to host interface 8, non-volatile memory 12, and volatile memory 10 in order to orchestrate data movement throughout non-volatile memory system 2. Executive 28 also receives various interrupts and information from host interface 8, non-volatile memory 12, and volatile memory 10. It is the responsibility of executive 28 to examine schedule 40 which contains various commands for data movement at specific power levels and enforce schedule 40 by initiating said commands of schedule 40 by interacting with host interface 8, non-volatile memory 12, and volatile memory 10. The power levels associated with these commands are also enforced by executive 28 via interaction with host interface 8, non-volatile memory 12, and volatile memory 10. Schedule 40 is updated from time to time and thus executive 28 must enforce changes in power levels of commands that have already been initiated as well as initiate new commands that have been added to schedule 40. Executive 28 stores any requests from host device 4 of FIG. 1 received via host interface 8 into the host requests data structure 34 which are subsequently used by scheduler 26. Executive 28 may optionally receive information regarding the present current limit which indicates, for example, the maximum amount of current that is permissible for use by non-volatile memory system 2. This information about the present maximum current limit is stored in current limit 32 and is subsequently accessed by scheduler 26. In another embodiment, current limit 32 is a static data structure which does not change over time. As will be appreciated by those of skill in the art, non-volatile memory system 2 of FIG. 1 may operate at different current levels with correspondingly different host devices 4, and even at different current levels within a single host device 4 according to present operating conditions. This is one exemplary reason why current limit 32 may be dynamic. It may be set only once at the beginning of operation once the various conditions have been detected, or, it may be fixed at the time of manufacture of non-volatile memory system 2. In this embodiment, current limit 32 may be stored as a parameter within a special system area of non-volatile memory 12 or may be hard coded into the circuitry of controller 6. As will be appreciated by those of skill in the art, various parameters stored in non-volatile memory 12 are moved to volatile memory 10 when non-volatile memory system 2 is powered up including data structures representing the current wear level of each physical block within non-volatile memory 12, etc. In certain embodiments, executive 28 may receive information via host interface 8, non-volatile memory 12, and volatile memory 10 regarding actual current consumption levels that are derived by empirical measurement. In this embodiment, executive 28 updates current consumption table 38 with up-to-date information. In another embodiment, current consumption table 38 contains fixed constants for the various operations enumerated in the table.

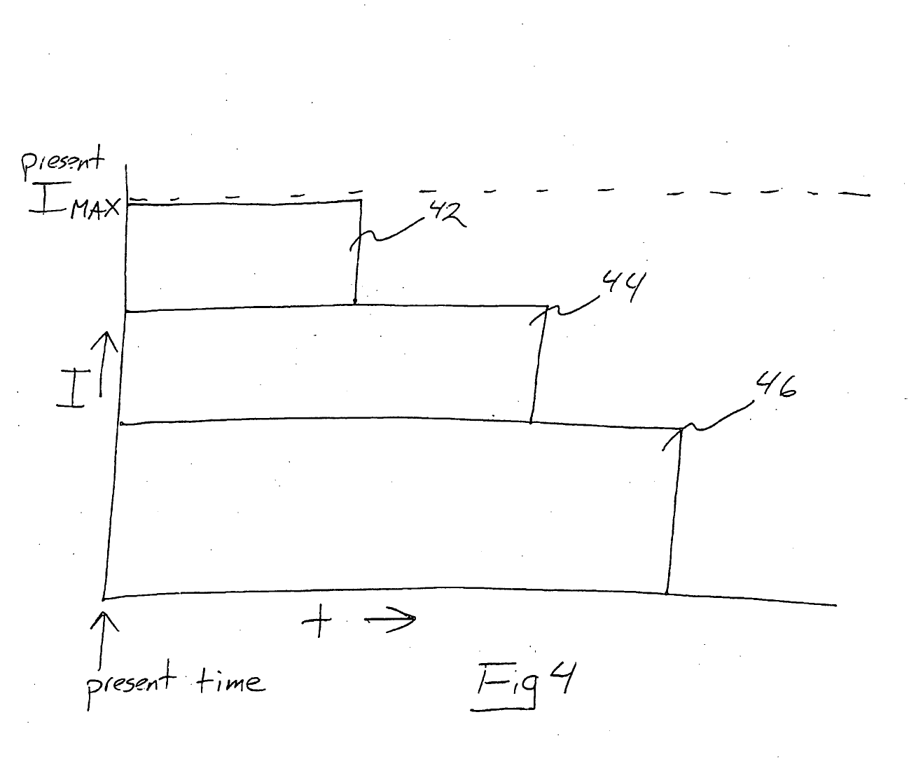

With continuing reference to FIG. 3, and with reference to FIG. 4, FIG. 4 depicts an operation of executive 28 with respect to schedule 40. The graph depicted in FIG. 4 represents time on the horizontal axis increasing from present time, on the far left, to future times on the right and current level is depicted on the vertical axis. The present maximum current level is shown in FIG. 4 as present IMAX and the associated-line. Three commands representing data movement, erasure, etc., are depicted as command 42, command 44 and command 46. The height of each of these commands represents the current level at which these commands are being carried out. The current levels of command 42, command 44 and command 46 when summed reveal the total current consumption at the present time and in a preferred embodiment, this total current consumption is less than or equal to the present maximum current depicted as present IMAX. As time progresses, the right edges of these various commands move closer to present time which is depicted on the far left. It is to be understood that the left side of this graph does not represent a fixed point in time but rather refers to the current time which is monotonically increasing. As time progresses, the right edge of the various commands draw closer to the present time until finally the shortest of these, in this case command 42, is depleted with the termination of command 42. In some embodiments, this results in an interrupt being generated by the hardware that was carrying out the task represented by command 42.

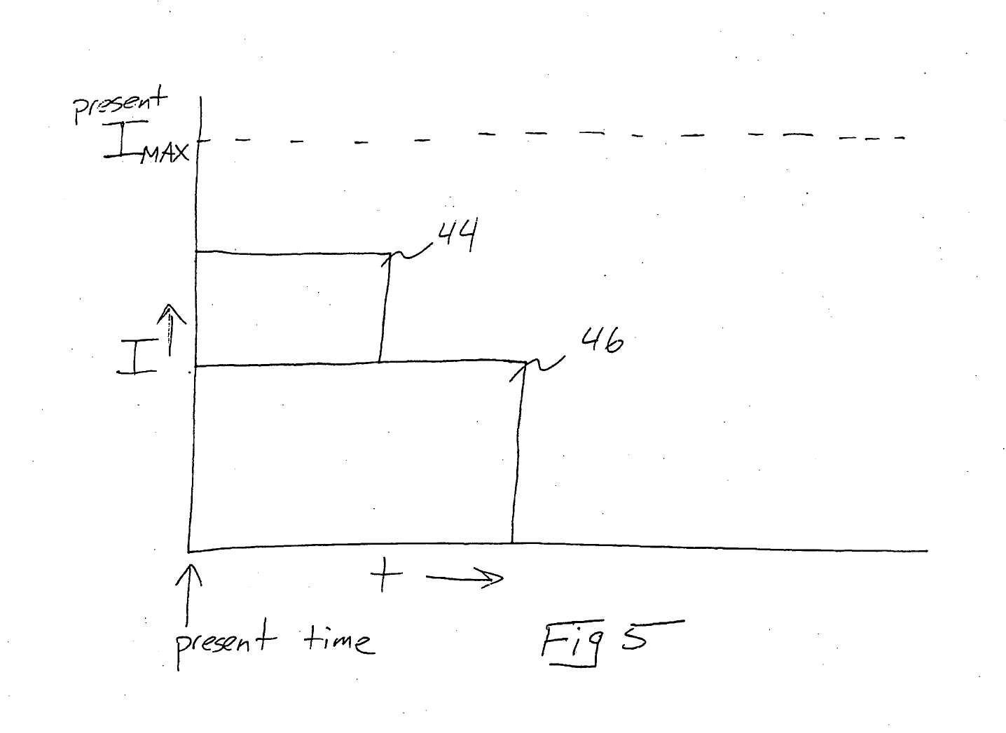

FIG. 5 depicts the current state of command execution at the moment command 42 is completed. As shown in FIG. 5, command 44 has been partially completed, as has command 46. As can be seen in FIG. 5, the current level consumed by the aggregate of command 44 and command 46 falls short of present IMAX which is derived from the current limit data structure 32 of FIG. 3. This means that non-volatile memory system 2 is operating at a current level which is less than its maximum allowable current level. In some cases, the extra current could be used to perform other pending tasks and or perform present tasks at a higher rate of performance. Further, the amount of unused current may be a very substantial fraction of the available current. As will be appreciated by those of skill in the art, this situation is sub-optimal because it means that substantially more time would be taken to complete commands 44 and 46 than is necessary. For this reason, the interrupt generated by the completion of command 42 induces a reevaluation by scheduler 26 of FIG. 3 which results in an update to schedule 40 and subsequent adjustments by executive 28. In some situations, additional commands may be added to schedule 40 which are detected by executive 28 which subsequently commands the hardware devices to initiate the new commands at the specified power levels and update currently executing commands to any new specification of power levels. To facilitate the detection of new commands, the data structure of schedule 40 may include a previous'state and a current state so that executive 40 may compare these respective states. Commands present in the current state and not present in the previous state would result in executive 28 initiating a command to the corresponding hardware device or devices.

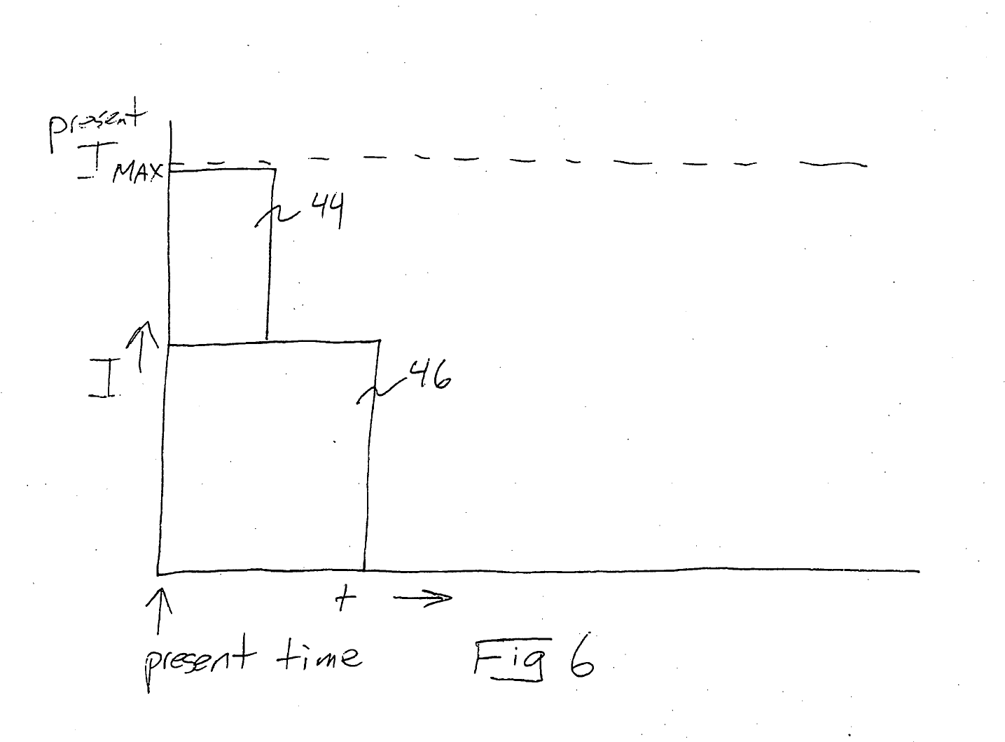

With continuing reference to FIG. 3, FIG. 6 depicts a scenario in which no additional commands are found in schedule 40. This scenario could occur if there were no commands waiting to be processed in host request data structure 34 or background task data structure 36. As can be seen in FIG. 6, the current levels for commands 44 and 46 have been adjusted and the sum of these current levels is near to or equal to the present current maximum depicted by present IMAX. It should be noted that present IMAX may be adjusted over time according to operating conditions that are present. Once executive 28 has initiated any new commands and power levels it enters a quiescent state. If any interrupts are received, executive 28 responds to these requests by updating the various data structures and/or reevaluating schedule 40. Certain tasks initiated by executive 28 result in additional tasks which must be performed. As will be appreciated by those of skill in the art, controller 6 of FIG. 1 is responsible for maintaining a logical to physical mapping which reconciles the logical address space of host device 4 and the physical address space of non-volatile memory 12. Some operations such as write operations to non-volatile memory 12 involve over-writing portions of the logical address space. In practice, this is carried out by, for example, writing the data to a new location and altering the mapping to reflect the new location as the location corresponding to the logical address to which the data was written. The previous physical address contains a previous state and must be erased before it is used again. Thus, in certain embodiments, executive 28 may alter background task data structure 36 to reflect that, for example, an erase operation must be performed at a given physical address. Other background tasks resulting from the initiation of various commands will be apparent to those skilled in the art.

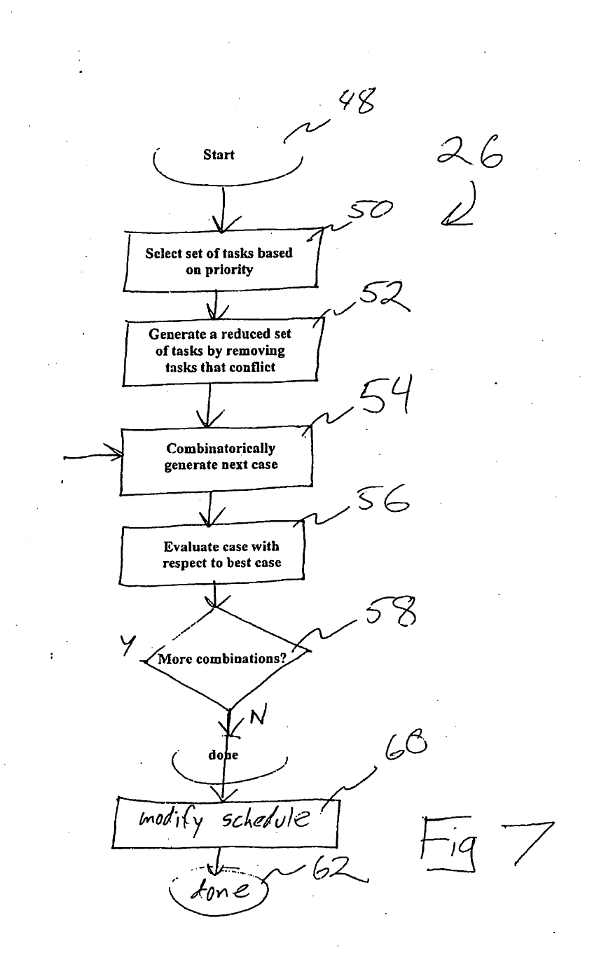

FIG. 7 depicts a scheduler process 26 of FIG. 3 in greater detail. The process begins in an operation 48 and continues in an operation 50 wherein a set of tasks are selected based on priority. These tasks are chosen from among the tasks represented within host request data structure 34 and background task data structure 36.

In one embodiment, at most a single task is selected. In other embodiments, multiple tasks may be selected.

In certain embodiments, the host request data structure 34 is considered to contain tasks which are of higher priority than those contained in background task data structure 36 because host request data structure 34 contains requests originating from host device 4 and any delay in the execution of these requests is perceived as unresponsiveness. In some situations, however, the tasks represented by background task data structure 36 are considered to be high priority tasks such as the situation where a program operation has been requested but the erase tasks are so backlogged that the host request cannot be performed.

In some embodiments, the priority of various of these background tasks is elevated when there is a depletion of freshly erased blocks in non-volatile memory 12. Operation 50 produces a small set of tasks collected from host request data structure 34 and background task data structure 36. In an operation 52, the set of tasks which was selected in operation 50 is reduced by removing any tasks that conflict with presently scheduled tasks represented in schedule 40, An example of a conflict would be a program operation occurring in parallel with another program operation. In certain embodiments, parallelism of this kind would not be allowed. Conflicts like these may be detected by examining the task set generated by operation 50 and the scheduled tasks represented in schedule data structure 40 and applying a set of rules.

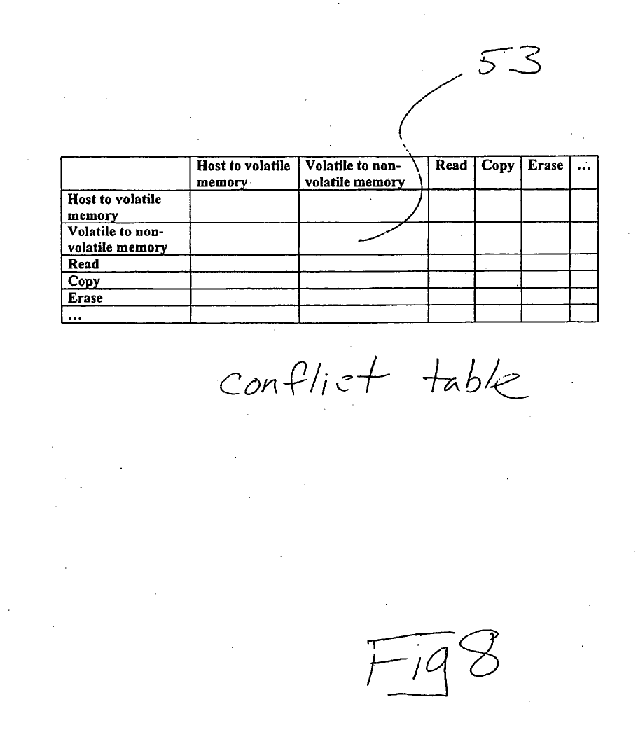

Such a set of rules could be encoded as a table in one embodiment such as that shown in FIG. 8 which depicts the various types of tasks both as rows and columns The cells of this grid contain a Boolean value which has the meaning of allowing or disallowing a particular kind of parallelism. For example, cell 53 of this table, represents whether or not data could be moved from volatile memory to non-volatile memory in parallel with a similar operation. A value of true in cell 53 would allow such an operation and a value of false would disallow such an operation. Once the conflicting tasks have been removed from the set, an operation 54 generates a next case which represents one possible configuration of commands to be loaded into schedule data structure 40. The combinatory engine of operation 54 generates every subset including the null set and the full set of tasks in the set generated by operations 50 and, then, reduced by operation 52. it also includes the full set of every task in operation 52 generated by operations 50 and 52.

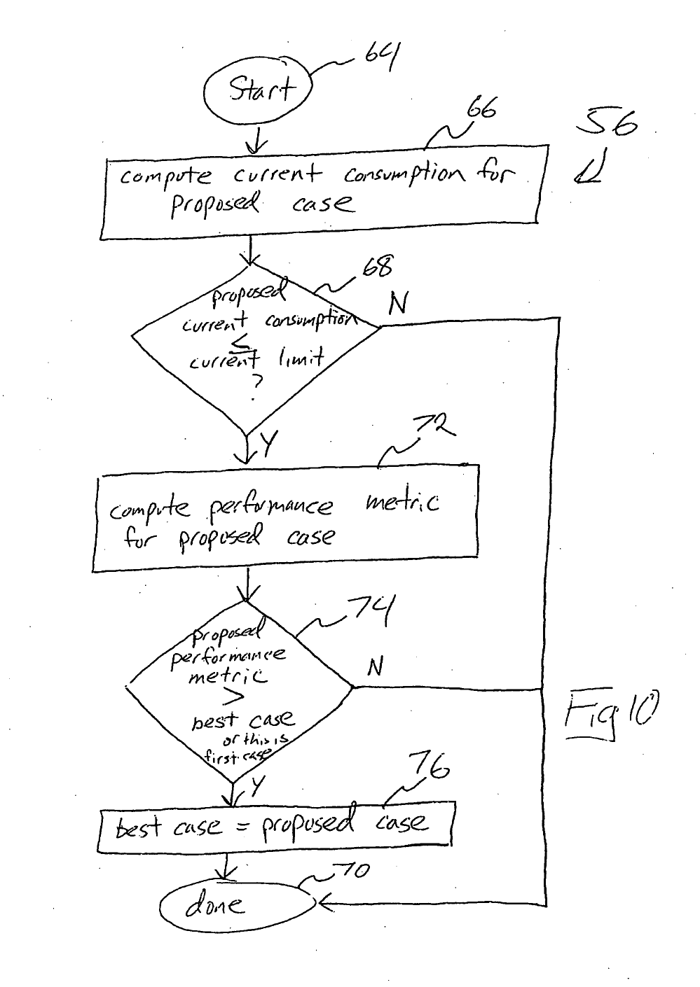

The cases generated by the combinatory process of operation 54 also include variations of power levels derived from current consumption table 38 shown in greater detail in FIG. 9. For each type of task a minimum K-value, maximum K-value, minimum I, maximum I, are enumerated. Minimum K-value represents the minimum performance level at which the given task may operate and the maximum K-value represents the maximum performance level at which this task can operate. Minimum I represents the current level associated with minimum K-value and maximum I represents the maximum current level associated with max K-value. As will be appreciated by those skilled in the art, linear interpolation or other methods may be used to determine intermediate values between these minimum and maximum values. The combinatory engine of operation 54 of FIG. 7, in one embodiment, may generate every combination for a given subset of tasks and additionally generate every combination of power levels for that set. In one embodiment, only minimum and maximum power levels are generated and in other embodiments, intermediate values may be generated. For example, in an embodiment where three power levels are generated, the power levels would include the minimum value, the maximum value, and a mid-point value. Other embodiments, would allow four or more power levels. A case generated by operation 54 always includes the currently scheduled operations, as well as a subset chosen from the set of tasks produced in operation 52. In general, it is the responsibility of the combinatory engine of operation 54 to generate a variety of sets of tasks at a variety of power levels.

This variety of cases allows the dynamic reallocation of current according to changing conditions, as signaled by various interrupt signals. A task that had previously been allocated a high current level could be reduced if said reduction is advantageous according to a performance metric.

The same set of tasks may be generated more than once by the combinatory engine of operation 54 because the power levels generated are varied from one case to the next. In an operation 56, the case generated by the combinatory engine of operation 54 is evaluated with respect to the best case that has been seen so far in this invocation of process 26 of FIG. 3. If it is determined that the case generated by operation 54 is better than the current best case, then, the current best case is replaced by the newly generated case. In a decision operation 58 it is determined whether or not there are more combinations to be generated by operation 54. If there are more combinations, control returns to operation 54 which generates the next case. If there are no more combinations to be considered, control passes to operation 60 which modifies schedule 40 according to the selected best case. The previous state of schedule 40 is retained in a separate data structure in certain embodiments. Once the schedule has been modified to reflect the current best case, the process is concluded in an operation 62.

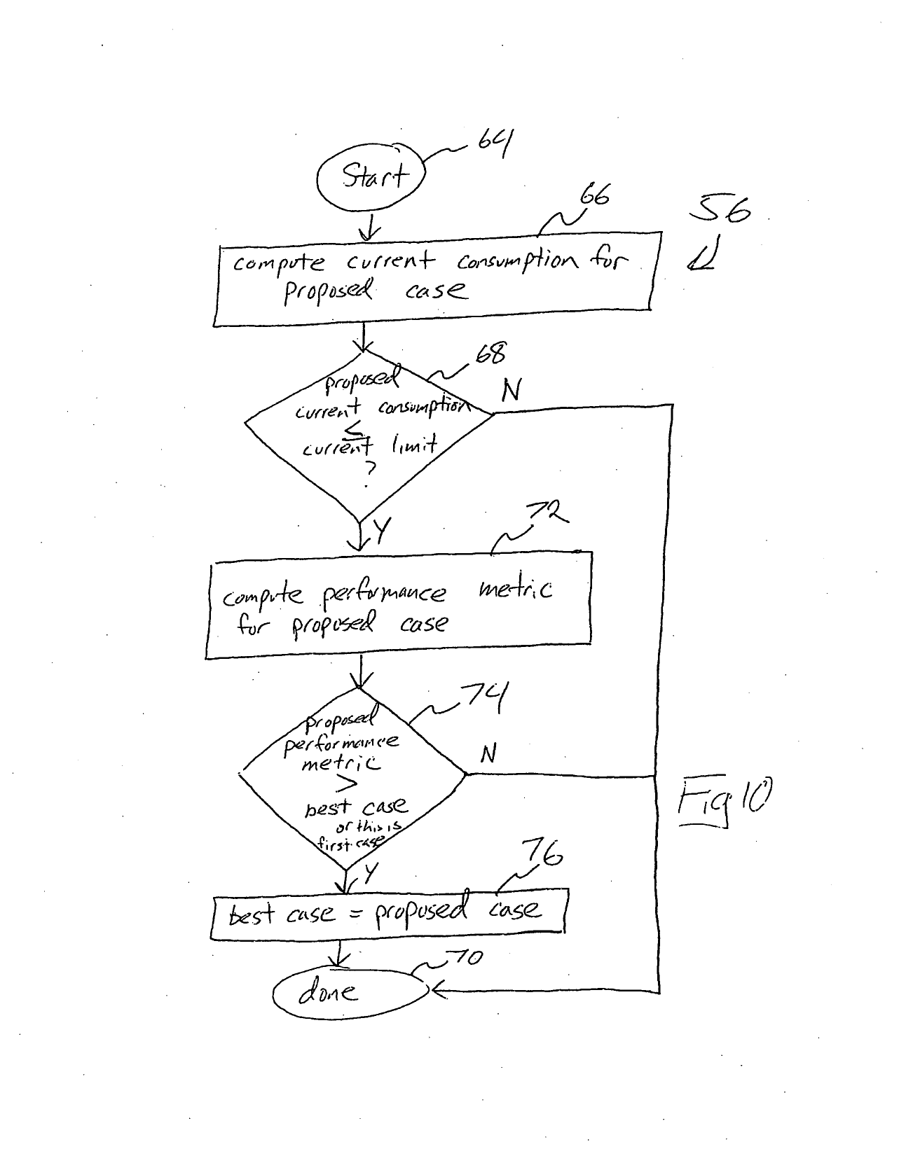

FIG. 10 is a flow diagram depicting an operation 56 of FIG. 7 in greater detail. The operation begins in an operation 64 and continues in an operation 66 wherein the current consumption for the proposed case is computed by summing the current values of the various tasks embodied in the case. In an operation 68, the proposed current consumption is compared to the current limit as represented in current limit data structure 32 of FIG. 3. If it is determined that the proposed current consumption is greater than the current limit, the operation is terminated in an operation 70. If, on the other hand, it is determined that the proposed current consumption is less than or equal to the current limit data structure 32 of FIG. 3, then control passes to operation 72 which computes a performance metric for the proposed case. In certain embodiments, the performance metric represents the total throughput of the proposed case, In another embodiment, the metric is characterized by the total current consumed. In an operation 74, the proposed performance is compared to the best case. If the proposed value exceeds that of the best case, control passes to an operation 76 which replaces the current best case with the proposed case. This path will always be taken if the proposed case is the first case. If it is determined in decision operation 74 that this is not the first case and the proposed performance metric does not exceed that of the best case, then, the operation is terminated in an operation 70. As will be appreciated by those skilled in the art, the embodiments disclosed herein describe a power management system which conforms to a given current limit and optimizes operations within that limit. This power management system has the property of graceful degeneration into a mode where operations are performed serially, not in parallel, and at reduced power levels. As will be further appreciated by those of skill in the art, this power management system gracefully scales to consume power that is allocated to it. At a certain high power level, max parallelism is achieved. As will be appreciated by those skilled in the art, various enhancements may be made to further increase performance within a fixed power budget. For example, locality of reference may be used to predict a location of future write operations which have not been received from host device 4. In one embodiment, write operations to a given portion of the logical address space of host device 4 will cause a boost of priority in maintenance tasks pertaining to other logical addresses near that logical address. Thus, when write operations are received from the host, which match these heuristically predicted locations, the write operations do not have to wait for the various maintenance tasks to be performed.

In certain embodiments, various data move operations are considered to have multiple parts or phases. For example, a write operation could be considered to have two phases, one which loads data into volatile memory and another which takes that data in volatile memory and programs the non-volatile memory. In one embodiment, these multiple parts are scheduled as two parts of the same operation and are not separated within the scheduler process 26.

The priority of the various tasks in host request data structure 34 and background task data structure 36 are in one embodiment dynamically evaluated based on when these requests were received and the type of task. Certain embodiments boost the priority of erase tasks when the condition arises that there are no more freshly erased physical sectors on which to write.

It should be noted that the power supply is often under the control of a user who can, for example, arbitrarily and without warning disconnect one or more sources of power. In some cases, an alternative source of power is available and thus operations may continue. In certain embodiments, the choice of dynamic power configuration will be limited to those configurations with task sets which may endure a sudden drop in power. In one embodiment, task sets which have a total minimum current level that is greater than the minimal current level that can be supplied after such a sudden loss would not be chosen.

Although various embodiments have been described using specific terms and devices, such description is for illustrative purposes only. The words used are words of description rather than of limitation. It is to be understood that changes and variations may be made by those of ordinary skill in the art without departing from the spirit or the scope of the present invention, which is set forth in the following claims. In addition, it should be understood that aspects of various other embodiments may be interchanged either in whole or in part. It is therefore intended that the claims be interpreted in accordance with the true spirit and scope of the invention without limitation or estoppel.

1. A method for power management in a system comprising:
determining a maximum system current level; and allocating current to one or more operations each having a minimum operation current level and a maximum operation current level such that the total allocated current for the one or more operations does not exceed the maximum system current level.

2. The method for power management in a system as recited in claim 1 wherein said allocating current to one or more operations includes a performance optimization operation.

3. The method for power management in a system as recited in claim 2 wherein said determining a maximum system current level includes obtaining information pertaining to operating conditions.

4. The method for power management in a system as recited in claim 3 wherein said information pertaining to operating conditions includes a type of a host device.

5. The method for power management in a system as recited in claim 3 wherein said information pertaining to operating conditions includes a maximum current level received from a host device.

6. The method for power management in a system as recited in claim 3 wherein said information pertaining to operating conditions includes information identifying the type of a power source.

7. The method for power management in a system as recited in claim 2 wherein said determining a maximum system current level utilizes a predetermined maximum current level.

8. The method for power management in a system as recited in claim 3 wherein said one or more operations comprises at least one of a data transfer from a host device to a volatile memory, a data transfer from a volatile memory to a non-volatile memory, a data transfer from a non-volatile memory to a volatile memory, a data transfer from a volatile memory to a host device, a data transfer from a non-volatile memory to a host device, and an erasure of at least a portion of a non-volatile memory.

9. The method for power management as recited in claim 8 wherein at least two operations are performed concurrently.

10. The method for power management as recited in claim 8 wherein a controller enters a sleep mode when a quiescent state of said controller is reached.

11. The method for power management as recited in claim 9 further comprising controlling at least one of a non-volatile memory, volatile memory, and a communications interface coupled to a host to perform said set of one or more operations at their respective current consumption levels.

12. The-method as recited in claim 9 wherein the current consumption levels associated with said set of one or more operations are chosen according to an associated performance level.

13. The method as recited in claim 9 wherein said allocating current to one or more operations is performed in response to a detected change in operating conditions.

14. The method as recited in claim 9 wherein said allocating current to one or more operations is performed in response to the completion of one or more operations.

15. Means for power management in a digital electronic device comprising:
means for dynamically determining a maximum current limit;
means for adjusting performance of said digital electronic device such that subsequent to said performance adjustment, performance is optimal or approximately optimal within the constraints imposed by said maximum current limit and current consumption in said digital electronic device is at or below said maximum current limit.

16. Means for power management in a digital electronic device as recited in claim 15 wherein said digital electronic device is a flash memory device.

17. Means for power management in a flash memory device as recited in claim 16 further comprising:
means for generating a plurality of current usage alternatives;
means for choosing one current usage alternative from said plurality of current usage alternatives;
means for actualizing said chosen current usage alternative such that current usage in said flash memory device reflects said chosen current usage alternative.

18. Means for power management in a flash memory device as recited in claim 16 further comprising means for reducing the power consumption of a controller during times of low usage or no usage.

19. Means for power management in a flash memory device as recited in claim 16 further comprising means for reevaluating current consumption in response to an interrupt.

20. Means for power management in a flash memory device as recited in claim 16 further comprising means for adapting to a sudden reduction in supplied current by reducing the performance of at least one operation of said flash memory device.

21. A method for power management on an NVM device, the method comprising: allocating current to one or more operations each having a minimum operation current level and a maximum operation current level such that the total allocated current for the one or more operations does not exceed a maximum current level.

22. An NVM device comprising: power control circuitry adapted to allocate current to one or more operations each having a minimum operation current level and a maximum operation current level such that the total allocated current for the one or more operations does not exceed a maximum current level.
